(19) United States
(12) Patent Application Publication
(10) Pub. No.: US 2012/0108105 A1
(43) Pub. Date: May 3, 2012

(54) PRESS-FIT MEANS AND ELECTRICAL CONNECTOR HAVING THE SAME

(75) Inventors: MU CHENG, Kunshan (CN); ZHI-GANG HE, Kunshan (CN)

(73) Assignee: HON HAI PRECISION INDUSTRY CO., LTD., New Taipei (TW)

(21) Appl. No.: 13/286,497

(22) Filed: Nov. 1, 2011

(30) Foreign Application Priority Data
Nov. 3, 2010 (CN) 201020589231.8

(51) Int. Cl. H01R 13/648; H05K 7/02

(52) U.S. Cl. 439/607.35; 361/809

(57) ABSTRACT

An electrical connector (100) includes a press-fit contact or terminal (1) for being press-fit mounted in a mounting hole of a circuit board. Each press-fit terminal includes a connecting portion (11), an end portion (13), and a hole portion (12) between the connecting portion and the end portion. The hole portion includes a pair of first resilient portions (121) branching from the connecting portion and respectively configured into an obliquely extending straight line, a pair of second resilient portions (122) branching from the end portion, and a deformable hole (123) surrounded by said first and second resilient portions.

### BACKGROUND OF THE INVENTION

1. Field of the Invention

The present invention relates to a press-fit means and an electrical connector having the same, and more particularly to a press-fit means mounted in a circuit board and a SFP (Small Form-factor Pluggable) connector using the same.

2. Description of Related Art

U.S. Pat. No. 6,655,995 issued to Reisinger et al. on Dec. 2, 2003 discloses a SFP transceiver connector including a cage. The cage includes a plurality of side walls having a plurality of press-fit means. U.S. Pat. No. 7,891,992 issued to Veigel on Feb. 22, 2011 discloses a press-fit contact or means. The press-fit means is adapted for being press-fit mounted in mounting holes of a circuit board. The press-fit means includes a connecting portion, an end portion, and an intermediate hole portion. The hole portion has a hole, a pair of curved first resilient portions and a pair of curved second resilient portions connected with each other to form a circular or elliptical periphery surrounding the hole.

In the above-mentioned prior art, in use, there is not a sufficiently large contact region between the press-fit means and the mounting hole of the circuit board, since the curved first resilient portions of the press-fit means would still remain curved in the mounting hole.

Hence, an improved press-fit means and an electrical connector having the same are desired.

### SUMMARY OF THE INVENTION

Accordingly, an object of the present invention is to provide a press-fit means having a pair of first resilient portions respectively configured into an obliquely extending straight line to obtain a large contact region, and an electrical connector having the same.

In order to achieve the object set forth, an electrical connector includes a press-fit contact or terminal for press-fit mounted in a mounting hole of a circuit board. Each press-fit terminal includes a connecting portion, an end portion, and a hole portion between the connecting portion and the end portion. The hole portion includes a pair of first resilient portions branching from the connecting portion and respectively configured into an obliquely extending straight line, a pair of second resilient portions branching from the end portion, and a deformable hole surrounded by said first and second resilient portions.

The first resilient portions of the press-fit terminal are respectively configured into an obliquely extending straight line and would become vertically extending straight line in use. The conventional press-fit means have curved or bent first resilient portions and would still remain curved or bent in use. Therefore, the length of the contact region of the present invention is larger than that of the conventional press-fit means. There is a sufficiently large contact region in the present invention.

Other objects, advantages and novel features of the invention will become more apparent from the following detailed description when taken in conjunction with the accompanying drawings.

### BRIEF DESCRIPTION OF THE DRAWINGS

FIG. 1 is a perspective view showing a press-fit means in an unused status in accordance with the present invention;

FIG. 2 is a front view showing the press-fit means in the unused status;

FIG. 3 is a front view showing the press-fit means in use; and

FIG. 4 is a perspective view showing the press-fit means applied in an electrical connector.

### DETAILED DESCRIPTION OF THE PREFERRED EMBODIMENT

Reference will now be made in detail to the preferred embodiment of the present invention.

An electrical connector 100 in accordance with the present inversion includes a press-fit means 1, i.e., a press-fit contact or terminal, adapted for being mounted in a mounting hole (not shown) of a mother board (not shown).

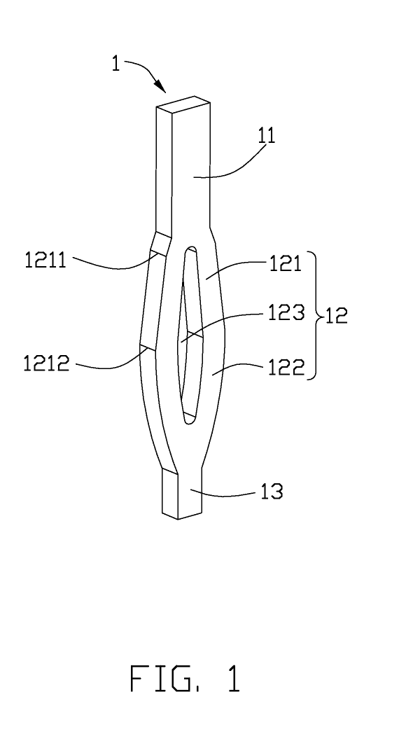

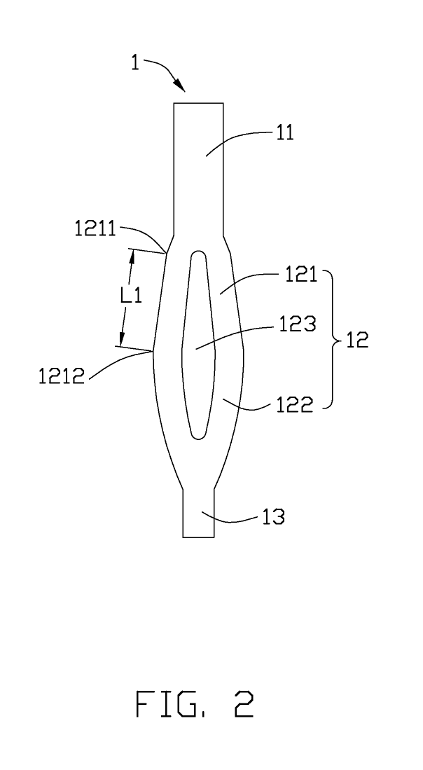

FIGS. 1 and 2 show the press-fit means 1 in an unused status. The press-fit means 1 includes a connecting portion 11, an end portion 13, and a hole portion 12 between the connecting portion 11 and the end portion 13. The connecting portion 11 could be connected with an electrical connector 100, or a contact terminal (not shown), or etc.

The hole portion 12 includes a pair of first resilient portions 121 downwardly branching from the connecting portion 11, a pair of curved second resilient portions 122 upwardly branching from the end portion 13, and a deformable hole 123 surrounded by the first and second resilient portions 121, 122. Each of the pair of first resilient portions 121 is configured into an obliquely extending straight line.

Each first resilient portion 121 defines a terminating point 1211 and an intergrading point 1212. The first resilient portion 121 is connected to the connecting portion 11 at the terminating point 1211, and is connected to the second resilient portion 122 at the intergrading point 1212. A distance between the pair of intergrading points 1212 is larger than that between the pair of terminating points 1211.

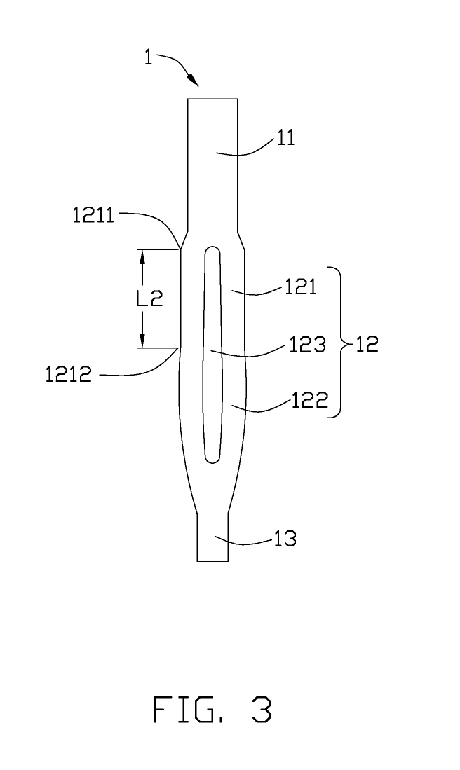

In conjunction with FIG. 3, in use, when the press-fit means 1 is press-fit mounted in the mounting hole of the circuit board, the end portion 13 is inserted across the mounting hole, and the first resilient portions 121 are respectively pressed into a vertically extending straight line in the mounting hole. A length L2 of a contact region between the press-fit means 1 and the mounting hole is substantially equal to a distance L1 between the terminating point 1211 and the intergrading point 1212 of the press-fit means 1 in an unused status.

The first resilient portions 121 of the press-fit means 1 of the present invention are respectively configured into obliquely extending straight line and would become vertically extending straight line in use. The conventional press-fit means have curved or bent first resilient portions and would still remain curved or bent in use. The length of the contact region of the present invention is larger than that of the conventional press-fit means. It is possible to obtain a maximum contact region in the present invention.

In addition, the press-fit means 1 of the present invention is press-fit mounted in the mounting hole of the circuit board under a force smaller than that of the conventional press-fit means. A detecting result is shown in the following graph.

| | Diameter of the | | |
|---|---|---|---|
| | mounting hole | Insertion force | Extracting force |
| Conventional | 0.56 mm | 1.40 kgf | 0.71 kgf |
| art | 0.61 mm | 1.07 kgf | 0.55 kgf |
| Present | 0.56 mm | 1.25 kgf | 0.35 kgf |
| invention | 0.61 mm | 0.99 kgf | 0.32 kgf |

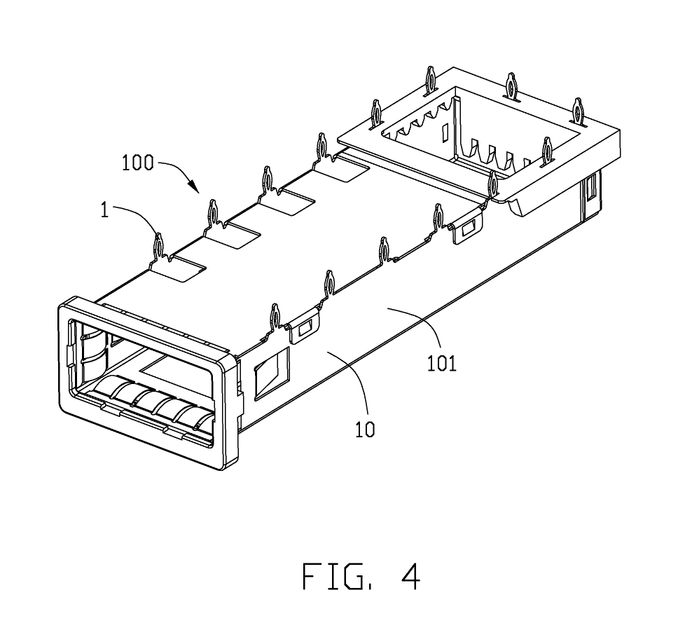

FIG. 4 shows the press-fit means 1 applied in the electrical connector 100. The electrical connector 100 comprises a shielding cage 10 including a pair of side walls 101 respectively having a plurality of press-fit means 1 extending downwardly from the side walls 101. When the shielding cage 10 of the electrical connector 100 is press-fit mounted in the circuit board, the press-fit means 1 are press-fit mounted in the mounting holes.

In another embodiment, the press-fit means 1 could be applied in a modular jack, or a shielding cage of another type of connector, or etc.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A press-fit means for being press-fit mounted in a mounting hole of a circuit board, comprising:
a connecting portion;
an end portion; and
a hole portion between the connecting portion and the end portion, said hole portion including a pair of first resilient portions branching from the connecting portion and respectively configured into an obliquely extending straight line, a pair of second resilient portions branching from the end portion, and a deformable hole surrounded by said first and second resilient portions.

2. The press-fit means as claimed in claim 1, wherein each of said first resilient portions defines a terminating point and an intergrading point, said first resilient portion connected to the connecting portion at the terminating point and connected to the second resilient portion at the intergrading point, a distance between the pair of intergrading points being greater than that between the pair of terminating points.

3. The press-fit means as claimed in claim 1, wherein said end portion is inserted across the mounting hole of the circuit board and said first resilient portions are respectively pressed into a vertically extending straight line in the mounting hole, when the press-fit means is mounted in the circuit board.

4. The press-fit means as claimed in claim 1, wherein said pair of second resilient portions are respectively configured in a curved shape.

5. An electrical connector, comprising:
a shielding cage including a wall having a plurality of press-fit means for being press-fit mounted in a mounting hole of a circuit board, each press-fit means including a connecting portion, an end portion, and a hole portion between the connecting portion and the end portion, said hole portion including a pair of first resilient portions branching from the connecting portion and respectively configured into an obliquely extending straight line, a pair of second resilient portions branching from the end portion, and a deformable hole surrounded by said first and second resilient portions.

6. The electrical connector as claimed in claim 5, wherein each of said first resilient portions defines a terminating point and an intergrading point, said first resilient portion connected to the connecting portion at the terminating point and connected to the second resilient portion at the intergrading point, a distance between the pair of intergrading points being greater than that between the pair of terminating points.

7. The electrical connector as claimed in claim 5, wherein said end portion is inserted across the mounting hole of the circuit board and said first resilient portions are respectively pressed into a vertically extending straight line in the mounting hole, when the press-fit means is mounted in the circuit board.

8. The electrical connector as claimed in claim 5, wherein said pair of second resilient portions are respectively configured in a curved shape.
